(19) United States
(12) Patent Application Publication
(10) Pub. No.: US 2024/0215223 A1
(43) Pub. Date: Jun. 27, 2024

(54) HOLE-TYPE SADP FOR 2D DRAM CAPACITOR

(71) Applicant: Applied Materials, Inc., Santa Clara, CA (US)

(72) Inventor: Fredrick Fishburn, Aptos, CA (US)

(73) Assignee: Applied Materials, Inc., Santa Clara, CA (US)

(21) Appl. No.: 18/385,945

(22) Filed: Nov. 1, 2023

Related U.S. Application Data
(60) Provisional application No. 63/434,149, filed on Dec. 21, 2022.
(60) Provisional application No. 63/440,000, filed on Jan. 19, 2023.

(51) Int. Cl. H10B 12/00

(52) U.S. Cl. CPC H10B 12/315; H10B 12/033; H10B 12/482; H10B 12/488; H10B 12/485

(57) ABSTRACT

Memory devices and methods of forming memory devices are described. Methods of forming electronic devices are described where a spacer is formed around each of the bit line contact pillars, the spacer in contact with the spacer of an adjacent bit line contact pillar. A doped layer is then epitaxially grown on the memory stack and bit line is formed on the memory stack. The bit line is self-aligned with the active region.

### CROSS-REFERENCE TO RELATED APPLICATIONS

This application claims priority to U.S. Provisional Application No. 63/434,149, filed Dec. 21, 2022, and to U.S. Provisional Application No. 63/440,000, filed Jan. 19, 2023, the entire disclosures of which are hereby incorporated by reference herein.

### TECHNICAL FIELD

Embodiments of the present disclosure pertain to the field of electronic devices and electronic device manufacturing. More particularly, embodiments of the disclosure provide DRAM devices with increased capacitor area density.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

The integrated circuit density on semiconductor substrates has dramatically increased, and the minimum feature sizes, such as the field effect transistor (FET) channel lengths and the word line widths on dynamic random-access memory (DRAM) have dramatically decreased. As the critical dimensions are reduced, etching to form the bit line is more challenging and leads to misalignment and poly-silicon string issues, such as skirt defect. Additionally, contact resistance increases, leading to lower drive current.

A significant barrier to further reduction in DRAM sizes is maintaining sufficient cell capacitances with good leakage and low density of cell-to-cell shorts. The average space between cells is 15 to 20 nm in order to fit the high-k dielectric and have at least a 10 nm margin against cell-to-cell leakage. Currently, the pitch between the memory cells of a DRAM device is about 40 nm and will need to decrease to less than 32 nm by the D1d node. A 16 nm diameter electrode will be used to have 16 nm average spacing between the cells for a 6-sigma minimum space of 12 nm. A space of 12 nm is needed between cell to fit two 5.5 nm layers of high-k dielectric material and still have a small gap for the top electrode. A space larger than 12 nm means that the hole could have been larger to increase the cell capacitance. Since the variability in hole size from cell-to-cell and top-to-bottom in a cell causes a smaller average cell size to be targeted, it can be appreciated that this variation results in a much lower average cell capacitance. Accordingly, methods to define the gap between cells to a range like 12 to 14 nm instead of 12-20 nm is needed.

Additionally, another difficulty in reducing DRAM sizes is the small pitch of the capacitor, which is on a hex layout at a pitch equal to the bit line (BL) pitch. The high aspect ratio (HAR) etch fixed the gap between the holes to satisfy the 12 nm final minimum gap means that the hole size is rapidly decreasing.

Therefore, there is an ongoing need in the art for improved DRAM devices and methods of forming DRAM devices.

### SUMMARY

One or more embodiments of the disclosure are directed to a hexagonal cell layout for a DRAM device. In one or more embodiments, the hexagonal cell layout comprises: a first placement layout comprising a plurality of first capacitor holes arranged in a center packed hexagonal pattern, each of the first capacitor holes having a length along a z-axis and a generally round cross-section in an x-y plane; and a second placement layout overlapping the first placement layout, the second placement layout comprising a plurality of second capacitor holes arranged in a second center packed hexagonal pattern interlaced with and offset by half a word line pitch and half a bit line pitch from the plurality of first capacitor holes to form the hexagonal cell layout, wherein each of the second capacitor holes have a length along the z-axis and a generally round cross-section with three arc shaped cutouts in the x-y plane to fit between each of the plurality of first capacitor holes.

Another embodiment of the disclosure is directed to a DRAM device. In one or more embodiments, a DRAM device comprises: a plurality of first capacitors arranged in a center packed hexagonal pattern, each of the first capacitors having a length along a z-axis and a generally round cross-section in an x-y plane; a plurality of second capacitors arranged in a second center packed hexagonal pattern interlaced with and offset by half a word line pitch and half a bit line pitch from the plurality of first capacitors so that an overall hexagonal array of alternating first capacitors and second capacitors is formed, each of the second capacitors having a length along the z-axis and a generally round cross-section with three arc shaped cutouts in the x-y plane to fit between each of the plurality of first capacitors; and a high-k material surrounding each of the pluralities of first capacitors and second capacitors.

A further embodiment of the disclosure is directed to a method of forming a DRAM device. In one or more embodiments, a method of forming a DRAM device comprises: forming a stack on an etch stop layer on a substrate, the stack comprising a core layer on an etch stop layer on a substrate, a support layer on a top surface of the core layer, a hardmask layer on the support layer, a hardmask opening layer on the hardmask layer, a second support layer on the hardmask opening layer, a DARC layer on the second support layer, and a photoresist layer on the DARC layer; etching a first set of hexagonal holes in the stack, the first set of hexagonal holes extending from a top surface of the photoresist layer to a top surface of the substrate; conformally depositing spacer layer in the first set of hexagonal holes; etching the stack and spacer layer to remove the spacer layer from a bottom surface of the first set of hexagonal holes; patterning and etching a second set of hexagonal holes adjacent to the first set of hexagonal holes; depositing a high-k material between the second set of hexagonal holes and the first set of hexagonal holes; and forming a top electrode on the second set of hexagonal holes and the first set of hexagonal holes to form a first set of capacitors and a second set of capacitors.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram of a method according to one or more embodiments;

FIG. 2 illustrates a cross-section view of a DRAM device according to one or more embodiments;

FIG. 3 illustrates a cross-section view of a DRAM device according to one or more embodiments;

FIG. 4A illustrates a cross-section view of a DRAM device according to one or more embodiments;

FIG. 4B illustrates a cross-section view of a DRAM device according to one or more embodiments;

FIG. 5 illustrates a cross-section view of a DRAM device according to one or more embodiments; and

FIG. 6 illustrates a cross-section view of a DRAM device according to one or more embodiments;

FIG. 7A illustrates a cross-section view of a layout to form a DRAM device according to one or more embodiments;

FIG. 7B illustrates a cross-section view of a layout to form a DRAM device according to one or more embodiments;

FIG. 8A illustrates a cross-section view of a DRAM device according to one or more embodiments;

FIG. 8B illustrates a cross-section view of a DRAM device according to one or more embodiments;

FIG. 9A illustrates a cross-section view of a DRAM device according to one or more embodiments;

FIG. 9B illustrates a cross-section view of a DRAM device according to one or more embodiments; and

FIG. 10 illustrates a cross-section view of a DRAM device according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The term “on” indicates that there is contact between elements, and there may be intervening elements or layers. The term “directly on” indicates that there is direct contact between elements with no intervening elements.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor.

As used herein, the term “capacitor” refers to an electrical component of a memory cell. A capacitor has two electrical conductors separated by electrically insulating material.

Some embodiments of the disclosure create capacitors with a space between them which maximizes the capacitor area. To do this, a smaller word line (WL) pitch and larger bit line (BL) pitch for a give WL pitch×BL pitch cell area. Without intending to be bound by theory, it is believed that the disclosed WL versus BL ratio is advantageous because the BL pitch scaling is more problematic than the WL. With a smaller WL pitch, the standard hexagonal capacitor layout is now formed by two sets of hexagonal capacitors offset by ½ WL pitch. In some embodiments, the two side-by-side capacitors are formed so that the space between them is uniform, defined by a spacer, and the thickness of the spacer will fit the high-k material with enough gap for a thin top electrode. The remaining space between the two offset, larger diameter, hexagonal layout cells is a small diameter hexagonal space. In some embodiments, the small diameter hexagonal holes act as the access point for lateral removal of the spacer, so that the high-k film can deposit on the electrodes with enough remaining gap to fit the minimum top electrode (˜1 nm).

Some embodiments of the disclosure use a word line pitch that is 0.578 times the bit line pitch compared to the current word line pitch that is 0.866 times the bit line pitch. This enables a dual hexagonal capacitor layout with the disclosed self-aligned double patterning (SADP) method.

The embodiments of the disclosure are described by way of the Figures, which illustrate devices (e.g., DRAM) and processes for forming DRAMs in accordance with one or more embodiments of the disclosure. The processes shown are merely illustrative possible uses for the disclosed processes, and the skilled artisan will recognize that the disclosed processes are not limited to the illustrated applications.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but may be to include deviations in shapes that result, for example, from manufacturing. Thus, the regions illustrated in the figures are schematic in nature and their shapes may be not intended to illustrate the actual shape of a region of a device and are not intended to limit the scope of example embodiments.

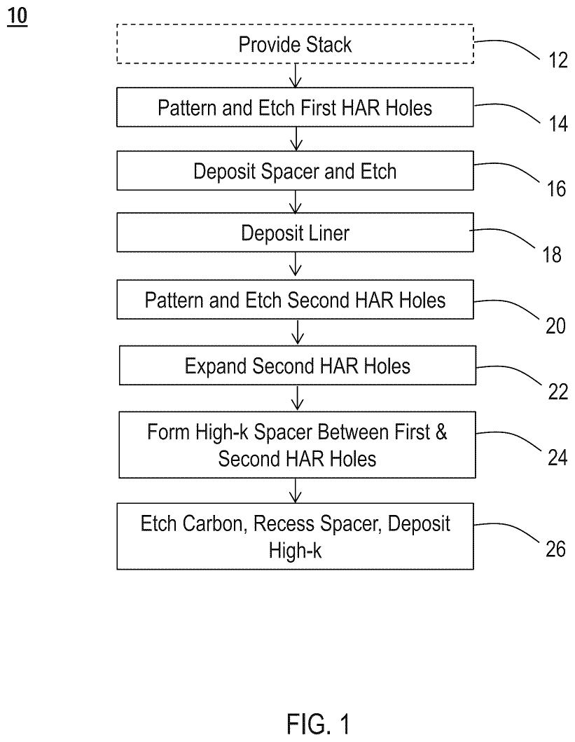

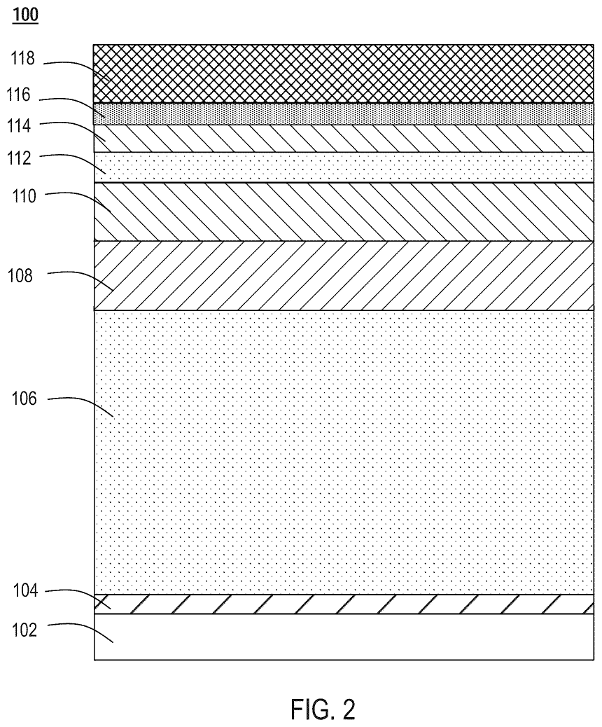

FIG. 1 illustrates a process flow diagram for a method 10 for forming a semiconductor device in accordance with some embodiments of the present disclosure. FIGS. 2-10 illustrate cross-sectional views of a semiconductor device, a DRAM in particular, according to one or more embodiments. The method 10 is described below with respect to FIGS. 2-10. The method 10 may be part of a multi-step fabrication process of a semiconductor device, a DRAM in particular.

In one or more embodiments, the method 10 may be performed in any suitable process chamber coupled to a cluster tool. The cluster tool may include process chambers for fabricating a semiconductor device, such as chambers configured for etching, deposition, physical vapor deposition (PVD), chemical vapor deposition (CVD), oxidation, or any other suitable chamber used for the fabrication of a semiconductor device.

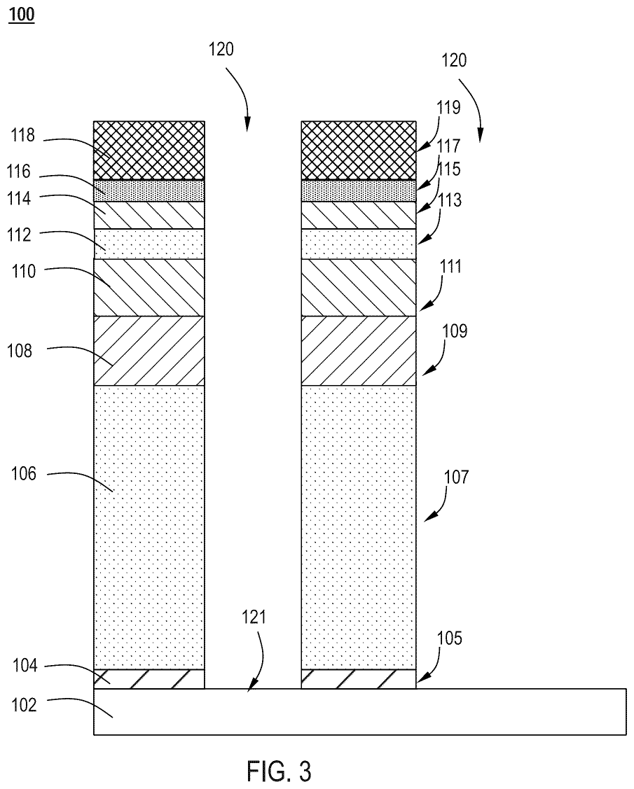

Referring to FIG. 1, at operation 12 of method 10, a stack for a self-aligned double patterning (SADP) capacitor is provided in order to form a 2D DRAM capacitor. As used in this specification and the appended claims, the term “provided” means that the stack is made available for processing (e.g., positioned in a processing chamber). In one or more embodiments, the stack is first formed by a series of deposition steps, as described below with respect to FIGS. 2 and 3. At operation 14, a set of first high aspect ratio (HAR) holes are etched. At operation 16, a spacer is deposited and then etched. At operation 18, a liner is deposited. At operation 20, a second set of high aspect ratio (HAR) holes are patterned and etched. At operation 22, the second set of HAR holes are expanded. At operation 24, a high-k spacer is formed between the first set and second set of HAR holes. At operation 26, the remaining core is removed, the spacer is recessed, and a high-k layer is deposited.

FIG. 2 illustrates a cross-section view of a stack of layers used in the formation of a DRAM capacitor. In one or more embodiments, the stack 100 comprises an etch stop layer 104 formed on a substrate 102. The etch stop layer 104 may comprise any suitable material known to the skilled artisan. In one or more embodiments, the etch stop layer 104 comprises one or more of a conformal layer of dielectric; SiN, SiCN, SiBN, SiON, and combinations thereof. The etch stop layer 104 may be deposited by any suitable technique known to the skilled artisan. In one or more embodiments, the etch stop layer 104 is deposited using a technique selected from CVD, PECVD, ALD deposition. The etch stop layer 104 may have any suitable thickness known to the skilled artisan. In one or more embodiments, the etch stop layer has a thickness in a range of from 0.5 nm to 100 nm, including in a range of from 1 nm to 50 nm, including in a range of from 3 nm to 25 nm, and including a range of from 3 nm to 10 nm.

In one or more embodiments, a core layer 106 is deposited on the top surface of the etch stop layer 104.

In one or more embodiments, the core layer 106 can comprise any suitable oxide material known to the skilled artisan. In one or more embodiments, core layer 106 comprises carbon. In one or more embodiments, the core layer 106 may be deposited at very high temperatures and have low hydrogen (H) content. In one or more embodiments, the core layer 106 comprises a dense, high temperature (500° C. or greater) plasma enhanced chemical vapor deposition (PECVD) carbon material.

Referring again to FIG. 2, in one or more embodiments, the core layer 106 may have any suitable thickness known to the skilled artisan. In one or more embodiments, the core layer has a thickness in a range of from 60 nm to 6000 nm, including in a range of from 150 nm to 2400 nm, and including in a range of from 300 nm to 1200 nm.

In one or more embodiments, the core layer 106 may be deposited by any suitable means known to the skilled artisan. In one or more embodiments, the core layer 106 may deposited by one or more of atomic layer deposition (ALD), chemical vapor deposition (CVD), and plasma enhanced chemical vapor deposition (PECVD).

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, “chemical vapor deposition” refers to a process in which a substrate surface is exposed to precursors and/or co-reagents simultaneous or substantially simultaneously. As used herein, “substantially simultaneously” refers to either co-flow or where there is overlap for a majority of exposures of the precursors.

Plasma enhanced chemical vapor deposition (PECVD) is widely used to deposit films due to cost efficiency and film property versatility. In a PECVD process, for example, a hydrocarbon source, such as a gas-phase hydrocarbon or a vapor of a liquid-phase hydrocarbon that have been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system. Any apparatus description described herein is illustrative and should not be construed or interpreted as limiting the scope of the embodiments described herein.

In one or more embodiments, the core layer 106 is deposited by plasma enhanced chemical vapor deposition (PECVD). In one or more embodiments, the PECVD may be performed at any suitable temperature. In specific embodiments, the PECVD deposition of the core layer 106 is conducted at a temperature in a range of from 300° C. to 700° C., including in a range of from 400° C. to 600° C., including in a range of from 450° C. to 550° C.

With reference to FIG. 2, a support layer 108 is deposited on the top surface of the core layer 106. The support layer 108 may comprise any suitable material known to the skilled artisan. In one or more embodiments, support layer 108 comprises a dielectric material.

As used herein, the term “dielectric material” refers to a layer of material that is an electrical insulator that can be polarized in an electric field. In one or more embodiments, the dielectric layer comprises one or more of oxides, carbon doped oxides, silicon oxide (SiOₓ), silicon nitride (SiN), silicon oxide/silicon nitride, carbides, oxycarbides, nitrides, oxynitrides, oxycarbonitrides, polymers, phosphosilicate glass, fluorosilicate (SiOF) glass, organosilicate glass (SiOCH), silicon carbo nitride (SiCN). In one or more embodiments, the dielectric layer includes, without limitation, furnace, CVD, PVD, ALD and spin-on-coat (SoC) deposited films. In one or more embodiments, the dielectric layer may be exposed to in-situ or ex-situ pretreatment and post-treatment process to dope, infuse, implant, heat, freeze, polish, etch, reduce, oxidize, hydroxylate, anneal, UV cure, e-beam cure and/or bake the surface or bulk of the dielectric. In one or more specific embodiments, the support layer 108 comprises silicon nitride (SiN). The silicon nitride (SiN) may be doped or undoped. In some embodiments, the silicon nitride is doped with carbon (SiCN).

In one or more embodiments, the support layer 108 may have any suitable thickness. In some embodiments, the support layer 108 has a thickness in a range of from 2 nm to 500 nm, including in a range of from 5 nm to 400 nm, including in a range of from 10 nm to 250 nm.

Referring to FIG. 2, a hardmask layer 110 is deposited on a top surface of the support layer 108. The hardmask layer 110 may comprise any suitable material known to the skilled artisan. In one or more embodiments, the hardmask layer 110 comprises one or more of silicon oxide (SiOx), silicon carbide (SiC), carbon doped hydrogenated silicon oxide (SiOCH), boron (B), boron nitride (BN), and the like. In one or more specific embodiments, the hardmask layer 110 comprises boronitride (BN).

The hardmask layer 110 may have any suitable thickness. In one or more embodiments, the hardmask layer 110 has a thickness in a range of from 20 nm to 1000 nm, including in a range of from 30 nm to 500 nm, including in a range of from 50 nm to 400 nm.

With reference to FIG. 2, a hardmask open layer 112 is deposited on a top surface of the hardmask layer 110. The hardmask open layer 112 may comprise any suitable material. In one or more embodiments, the hardmask open layer 112 comprises carbon. The hardmask open layer 112 may have any suitable thickness. In one or more embodiments, the hardmask open layer 112 has a thickness in a range of from 20 nm to 1000 nm, including in a range of from 30 nm to 500 nm, including in a range of from 50 nm to 300 nm.

Referring to FIG. 2, a second support layer 114 is deposited on a top surface of the hardmask open layer 112. The second support layer 114 may comprise any suitable material known to the skilled artisan. In one or more embodiments, second support layer 114 comprises a dielectric material. In one or more specific embodiments, the second support layer 114 comprises silicon nitride (SiN). The silicon nitride (SiN) may be doped or undoped. In some embodiments, the silicon nitride is doped with carbon (SiCN).

In one or more embodiments, the second support layer 114 may have any suitable thickness. In some embodiments, the second support layer 114 has a thickness in a range of from 2 nm to 500 nm, including in a range of from 5 nm to 400 nm, including in a range of from 10 nm to 250 nm.

Still referring to FIG. 2, in one or more embodiments, a dielectric anti-reflective coating (DARC) layer 116 is formed on a top surface of the second support layer 114. A DARC layer is an anti-reflective material commonly used to absorb radiation reflected from the substrate surface during photo imaging operations of semiconductor processing. In one or more embodiments, the DARC layer 116 may comprise any suitable material known to the skilled artisan. In one or more embodiments, the DARC layer 116 may have any suitable thickness. In some embodiments, the DARC layer 116 has a thickness in a range of from 1 nm to 100 nm, including in a range of from 2 nm to 75 nm, and including in a range of from 5 nm to 60 nm.

With reference to FIG. 2, a photoresist layer 118 is formed on a top surface of the DARC layer 116. The photoresist layer 118 may comprise any suitable material known to the skilled artisan and may have any suitable thickness. In one or more embodiments, the photoresist layer 118 has a thickness in a range of from 30 nm to 300 nm.

FIG. 3 illustrates a cross-section view 100 of the stack of layers used in the formation of a DRAM capacitor having a plurality of openings 120 etched therein. Referring to FIG. 1 and FIG. 3, at operation 14, in one or more embodiments, a plurality of openings 120 are formed in the stack by etching from a top surface of the photoresist layer 118 through the DARC layer 116, through the second support layer 114, through the hardmask open layer 112, through the hardmask layer 110, through the support layer 108, through the core layer 106, and through the etch stop layer 104 to expose a top surface of the substrate 102. Thus, in one or more embodiments, each of the plurality of openings 120 extends from a top surface of the photoresist layer 118 to the top surface of the substrate 102.

In one or more embodiments, sidewall surfaces 105, 107, 109, 111, 113, 115, 117, 119, and bottom 121 are formed within the opening 120 of the stack. In one or more embodiments, the opening 120 extends from a top surface of the photoresist layer 118 through to a top surface of the substrate 102.

In one or more embodiments, the plurality of openings 120 are high aspect ratio (HAR) openings. In one or more embodiments, the aspect ratio of the plurality of openings 120 is in a range of from 20:1 to 100:1.

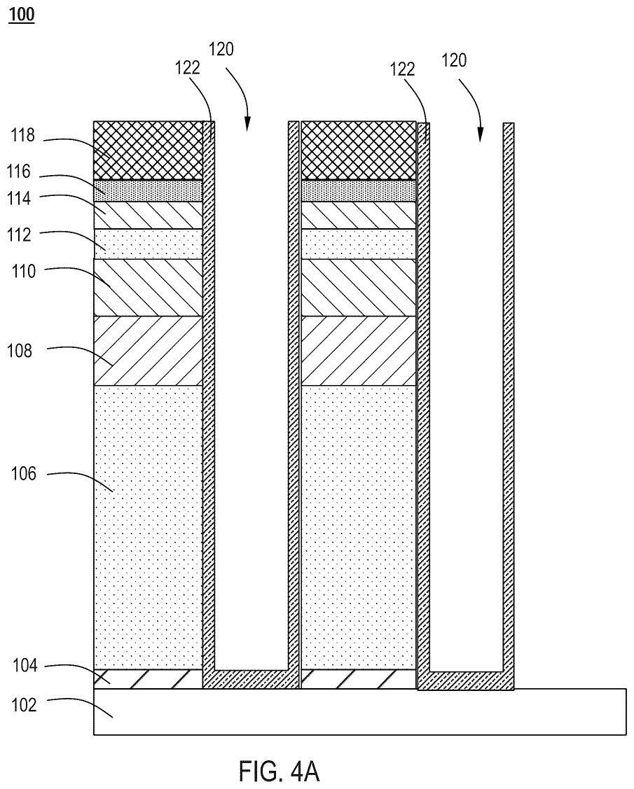

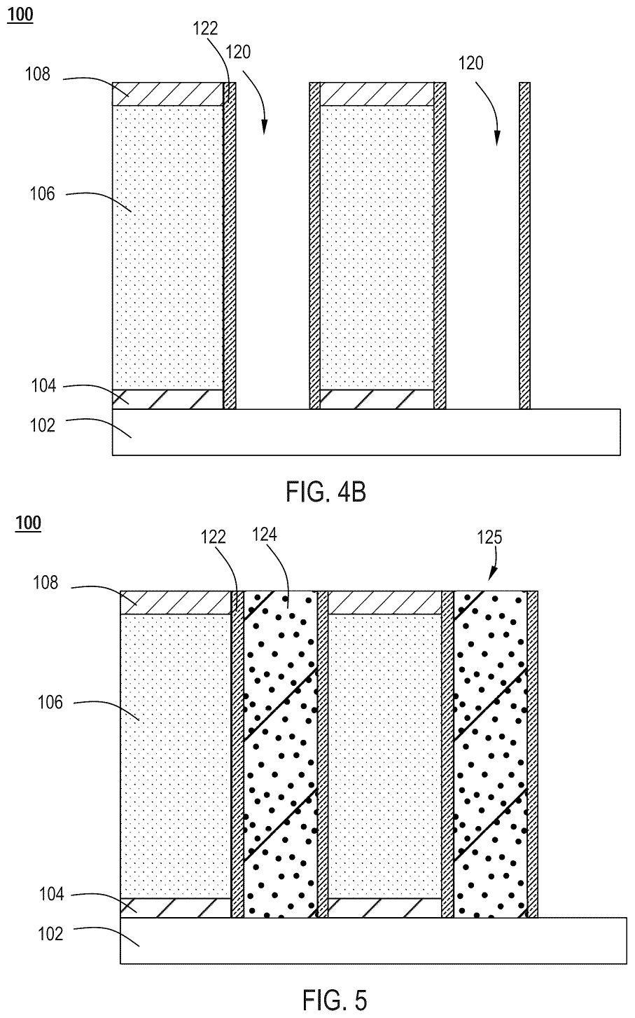

With reference to FIG. 1 and FIG. 4A, at operation 16, a spacer film 122 is deposited in the plurality of openings 120. The spacer film 122 is deposited on sidewall surfaces 105, 107, 109, 111, 113, 115, 117, 119, and bottom 121 within the opening 120 of the stack. Referring to FIG. 4B, in one or more embodiments, the spacer film is removed from the bottom 121 of the opening 120 and the hardmask layers are removed, exposing a top surface of support layer 108.

The spacer film 122 may comprise any suitable material known to the skilled artisan. In one or more embodiments, the spacer film 122 comprises an oxide. The spacer film 122 may have any suitable thickness. In one or more embodiments, the spacer film has a thickness in a range of from 0.5 nm to 10 nm, including a range of from 1 nm to 8 nm, and including a range of from 2 nm to 5 nm.

In some embodiments, the spacer film 122 is deposited conformally on the sidewall surfaces 105, 107, 109, 111, 113, 115, 117, 119, and bottom 121 within the opening 120 of the stack. As used herein, the term “conformal”, or “conformally”, refers to a film that adheres to and uniformly covers exposed surfaces with a thickness having a variation of less than 5%, less than 2%, or less than 1% relative to the average thickness of the film. For example, a 1,000 Å thick film may have less than a 10 Å variation in thickness. This thickness and variation include at least edges, corners, sides, and the bottom of recesses. For example, a conformal film deposited by ALD in various embodiments of the disclosure would provide coverage over the deposited region of essentially uniform thickness on complex surfaces.

Referring to FIG. 1 and FIG. 5, at operation 18, a liner layer 124 is deposited on the spacer film 122 in the opening 120. In one or more embodiments, the liner layer 124 fills the opening 120. In other embodiments, the liner layer 124 is a thin layer that is deposited conformally on the spacer film 122. The liner layer 124 may comprise any suitable material. In one or more embodiments, the liner layer 124 comprises one or more of titanium nitride (TiN), tantalum nitride (TaN), tungsten nitride (WN), and the like. The liner layer 124 may have any suitable thickness. In one or more embodiments, the liner layer has a thickness in a range of from 1 nm to 15 nm, including in a range of from 2 nm to 10 nm. The combination of the spacer layer 122 and the liner layer 124 forms the pillar 125.

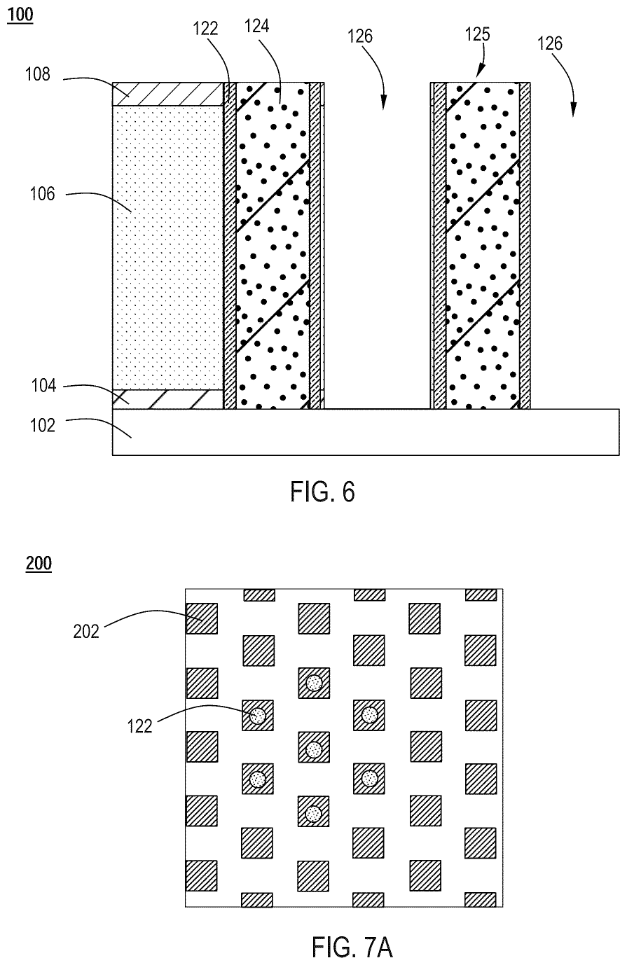

With reference to FIG. 1 and FIG. 6, at operation 20, the stack is patterned (with the deposition and removal of various unillustrated hardmask films) and etched form a second set of openings 126 adjacent to the pillars 125. After deposition of a spacer material and a liner material (not illustrated), the second set of openings 126 become a second set of pillars 127.

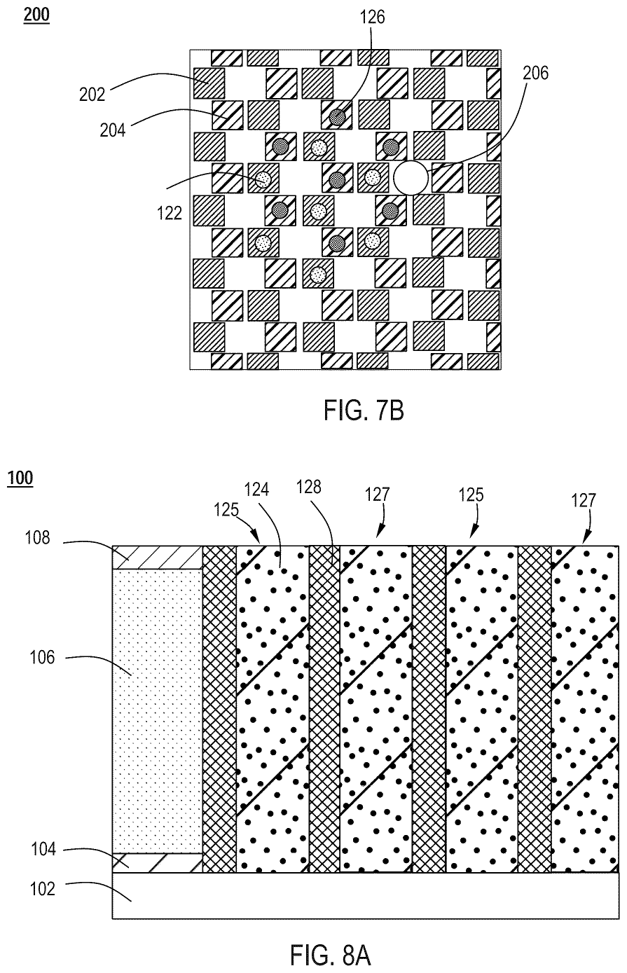

FIGS. 7A and 7B show how the two hex pattern described above can form a hex grid with an access hole. In FIG. 7A, the first placement layout 202 shows the first opening 120 which form the first set of capacitors 125. FIG. 7B illustrates the second placement layout 204 on top of the first placement layout 202 to form the second set of openings 126 which form the second set of capacitors 127. The access point 206 is later used for core removal and deposition of a high-k material and top electrode.

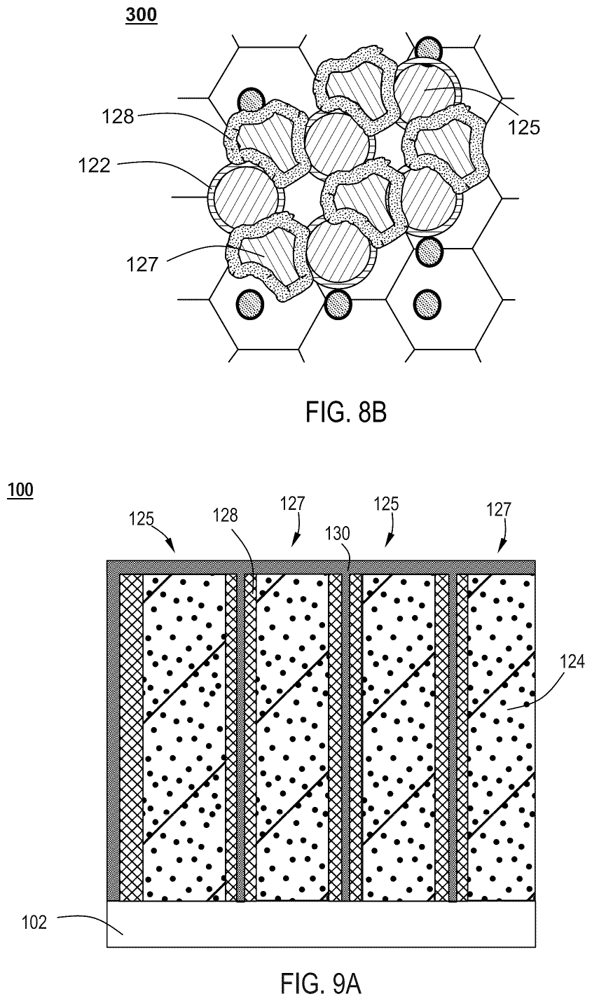

Referring now to FIG. 1 and FIGS. 8A and 8B, at operation 22, the second set of openings 126 are expanded. At operation 24, a spacer material and a liner material are deposited to form the second set of pillars 127. Between the first set of pillars 125 and the second set of pillars 125, a high-k spacer material 128 is deposited. The high-k spacer material 128 can comprise any suitable high-k material known to the skilled artisan. In one or more embodiments, the high-k material comprises zirconium oxide (ZrOₓ).

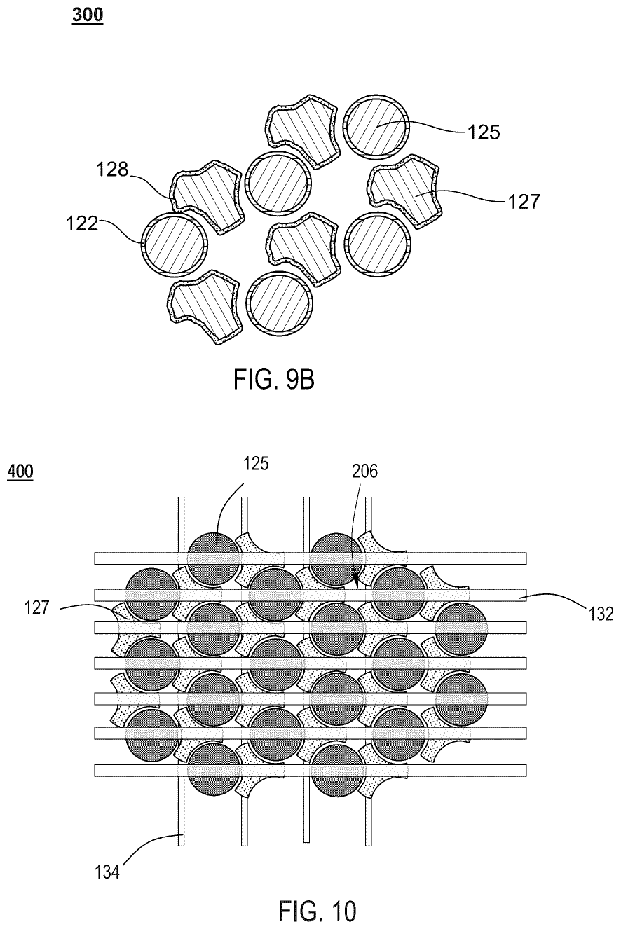

With reference to FIG. 1 and FIGS. 9A and 9B, at operation 26, the remaining core layer 106, etch stop layer 104, and support layer 108 are removed through the access point 206. A high-k spacer material 128 is recessed and a top electrode 130 is formed. The top electrode 130 can comprise any suitable material. In one or more embodiments, the top electrode 130 comprises one or more of titanium (Ti), titanium nitride (TiN), tantalum (Ta), and tantalum nitride (TaN).

FIG. 10 illustrates a cross-section view 400 of the DRAM device including a plurality of first capacitors 125 arranged in a center packed hexagonal pattern. Each of the first capacitors 125 have a length along a z-axis and a generally round cross-section in the x-y plane. A plurality of second capacitors 127 are arranged in a second center packed hexagonal pattern interlaced with the plurality of first capacitors 125 so that an overall hexagonal array of alternating first capacitors 125 and second capacitors 127 is formed. Wordlines 132 and bitlines 134 are connected to each of the capacitors 125, 127. The wordlines 132 have a pitch equal to less than 0.6× a bitline pitch. The plurality of second capacitors 127 are offset by half a word line pitch and half a bit line pitch from the plurality of first capacitors 125. Each of the second capacitors 127 have a length along the z-axis and a generally round cross-section with three arc shaped cutouts in the x-y plane to fit between the first capacitors 125. Each of the pluralities of first capacitors 125 and second capacitors 127 are surrounded by a high-k material and separated from adjacent capacitors by a spacer material. The high-k material can comprise any suitable material known to the skilled artisan. In one or more embodiments, the high-k material comprises zirconium oxide (ZrOₓ). The average gap between adjacent capacitors 125, 127 is in the range of 12 nm to 20 nm. An access point 206, located between the plurality of first capacitors and between the plurality of second capacitors, is used for removal of a core material during processing.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A hexagonal cell layout for a DRAM device, the hexagonal cell layout comprising:
a first placement layout comprising a plurality of first capacitor holes arranged in a center packed hexagonal pattern, each of the first capacitor holes having a length along a z-axis and a generally round cross-section in an x-y plane; and
a second placement layout overlapping the first placement layout, the second placement layout comprising a plurality of second capacitor holes arranged in a second center packed hexagonal pattern interlaced with and offset by half a word line pitch and half a bit line pitch from the plurality of first capacitor holes to form the hexagonal cell layout, wherein each of the second capacitor holes have a length along the z-axis and a generally round cross-section with three arc shaped cutouts in the x-y plane to fit between each of the plurality of first capacitor holes.

2. A DRAM device comprising:
a plurality of first capacitors arranged in a center packed hexagonal pattern, each of the first capacitors having a length along a z-axis and a generally round cross-section in an x-y plane;
a plurality of second capacitors arranged in a second center packed hexagonal pattern interlaced with and offset by half a word line pitch and half a bit line pitch from the plurality of first capacitors so that an overall hexagonal array of alternating first capacitors and second capacitors is formed, each of the second capacitors having a length along the z-axis and a generally round cross-section with three arc shaped cutouts in the x-y plane to fit between each of the plurality of first capacitors; and
a high-k material surrounding each of the pluralities of first capacitors and second capacitors.

3. The DRAM device of claim 2, wherein each of the pluralities of first capacitors and second capacitors are separated from adjacent capacitors by a spacer material.

4. The DRAM device of claim 2, wherein an average gap between adjacent capacitors is in a range of 12 nm to 20 nm.

5. The DRAM device of claim 2, further comprising wordlines and bitlines connected to each of the capacitors, the wordlines having a pitch equal to less than 0.6× a bitline pitch.

6. The DRAM device of claim 2, further comprising an access point located between the plurality of first capacitors and between the plurality of second capacitors.

7. The DRAM device of claim 2, wherein the plurality of first capacitors and the plurality of second capacitors independently comprise a metal selected from one or more of tungsten (W) or titanium nitride (TiN).

8. The DRAM device of claim 2, wherein the high-k material comprises zirconium oxide (ZrOₓ).

9. A method of forming a DRAM device, the method comprising:
forming a stack on an etch stop layer on a substrate, the stack comprising a core layer on an etch stop layer on a substrate, a support layer on a top surface of the core layer, a hardmask layer on the support layer, a hardmask opening layer on the hardmask layer, a second support layer on the hardmask opening layer, a DARC layer on the second support layer, and a photoresist layer on the DARC layer;
etching a first set of hexagonal holes in the stack, the first set of hexagonal holes extending from a top surface of the photoresist layer to a top surface of the substrate;
conformally depositing spacer layer in the first set of hexagonal holes;
etching the stack and spacer layer to remove the spacer layer from a bottom surface of the first set of hexagonal holes;
patterning and etching a second set of hexagonal holes adjacent to the first set of hexagonal holes;
depositing a high-k material between the second set of hexagonal holes and the first set of hexagonal holes; and
forming a top electrode on the second set of hexagonal holes and the first set of hexagonal holes to form a first set of capacitors and a second set of capacitors.

10. The method of claim 9, wherein the core layer comprises a carbon material.

11. The method of claim 9, wherein the support layer and second support layer independently comprise one or more of silicon carbonitride (SiCN), silicon nitride (SiN), and silicon oxide (SiO₂).

12. The method of claim 9, wherein the hardmask layer comprises one or more of silicon oxide (SiOx), silicon carbide (SiC), carbon doped hydrogenated silicon oxide (SiOCH), boron (B), and boron nitride (BN).

13. The method of claim 9, wherein the hardmask layer comprises boron (B) or boron nitride (BN).

14. The method of claim 9, wherein the top electrode comprises one or more of titanium (Ti), titanium nitride (TiN), tantalum (Ta), and tantalum nitride (TaN).

15. The method of claim 9, wherein the first set of capacitors and the second set of capacitors are separated from adjacent capacitors by the high-k material.

16. The method of claim 9, wherein an average gap between adjacent capacitors is in a range of 12 nm to 20 nm.

17. The method of claim 9, further comprising forming wordlines and bitlines connected to each of the capacitors.

18. The method of claim 17, wherein the wordlines have a pitch equal to less than 0.6× a bitline pitch.

19. The method of claim 9, wherein the first set of capacitors and the second set of capacitors independently comprise a metal selected from one or more of tungsten (W) or titanium nitride (TiN).

20. The method of claim 9, wherein the high-k material comprises zirconium oxide (ZrOₓ).
